(19) United States
(12) Patent Application Publication
(10) Pub. No.: US 2026/0337121 A1
(43) Pub. Date: Oct. 29, 2026

(54) METHOD FOR PRODUCING CERAMIC SUBSTRATE

(71) Applicant: AMOGREENTECH CO., LTD., Gimpo-si, Gyeonggi-do (KR)

(72) Inventor: Jihyung LEE, Gimpo-si (KR)

(73) Assignee: AMOGREENTECH CO., LTD., Gimpo-si, Gyeonggi-do (KR)

(21) Appl. No.: 19/107,937

(22) PCT Filed: Aug. 30, 2023
(86) PCT No.: PCT/KR2023/012841

§ 371 Date: Feb. 28, 2025

(30) Foreign Application Priority Data
Sep. 2, 2022 (KR) 10-2022-0111358

(51) Int. Cl. C04B 41/53; C04B 41/45

(52) U.S. Cl. CPC C04B 41/5338; C04B 41/4562; C04B 41/4572

(57) ABSTRACT

The present disclosure relates to a ceramic substrate manufacturing method, and is configured such that each of upper and lower metal layers bonded to top and bottom surfaces of a ceramic base is formed at a thickness of 0.8 mm or more, thus enabling application to a high-power power module, and such that press processing or cutting processing that is a mechanical processing method is conducted in advance to form a plurality of metal patterns on the upper metal layer, thus shortening the time required for a chemical etching process.

### TECHNICAL FIELD

The present disclosure relates to a ceramic substrate manufacturing method, and more particularly to a ceramic substrate manufacturing method that can reduce time and cost required to form a metal pattern on an upper metal layer.

### BACKGROUND ART

Generally, an electric vehicle requires an inverter that converts a Direct Current (DC) voltage provided by a high voltage battery into a 3-phase Alternating Current (AC) voltage required to drive a motor.

A power module for controlling the high voltage of a driving battery to a state suitable for the motor and supplying the controlled voltage is assembled with the inverter. The power module may include a semiconductor chip for converting power, and a ceramic substrate in which the semiconductor chip is mounted and connected through wire bonding. Here, the semiconductor chip generates high temperature heat due to a high voltage and high current operation. When such heat persists, a problem arises in that the semiconductor chip is degraded and the performance of the power module is deteriorated.

In order to solve this problem, a ceramic substrate to which a thick metal electrode having high thermal conductivity is applied is used, and due to the large thickness of the metal electrode, the dimensions of lines/spaces of the ceramic substrate are relatively large. Here, each line indicates a pattern which protrudes upwardly from the plane and extends in a line shape, and each space indicates a gap between lines, wherein the dimensions of the line/space refer to the widths of the corresponding line and the corresponding space in a direction parallel to the plane. For example, when the thickness is 0.3 mm, the line/space may form a circuit having a thickness of 0.5 mm, wherein the time required for an etching process is about 1 hour. On the other hand, when the thickness is 0.8 mm, the line/space need to form a circuit having a thickness of 1.6 mm, and thus a time of about 24 hours or longer is required for an etching process, thus resulting in significant inefficiency.

### SUMMARY OF INVENTION

### Technical Problem

The present disclosure has been made keeping in mind the above problems, and an object of the present disclosure is to provide a ceramic substrate manufacturing method, which performs a mechanical process of forming an upper pattern groove before an etching process during a patterning process of forming a metal pattern on a metal layer of a ceramic substrate, thus enabling cost reduction and efficient mass production.

### Solution to Problem

To achieve the above object, a ceramic substrate manufacturing method according to an embodiment of the present disclosure may include preparing an upper metal layer and a lower metal layer that are arranged on a top and a bottom of a ceramic base, forming an upper pattern groove having a thickness less than a thickness of the upper metal layer by applying heat and pressure to a partial upper portion of the upper metal layer, forming a photoresist pattern that exposes the upper pattern groove on a top surface of the upper metal layer, and etching a portion of the upper metal layer corresponding to the upper pattern groove by using the photoresist pattern as an etching mask.

In the forming of the upper pattern groove, the upper pattern groove may be formed to have a thickness equal to or greater than 50% and less than or equal to 90% of the thickness of the upper metal layer.

The ceramic substrate manufacturing method may further include, before or after the forming of the upper pattern groove, bonding the upper metal layer to a top of the ceramic base and bonding the lower metal layer to a bottom of the ceramic base.

The bonding may include arranging a bonding layer between a top surface of the ceramic base and a bottom surface of the upper metal layer and between a bottom surface of the ceramic base and a top surface of the lower metal layer, and bonding the ceramic base, the upper metal layer, and the lower metal layer by melting the bonding layer.

Further, the ceramic substrate manufacturing method according to an embodiment of the present disclosure may further include etching an exposed portion of the bonding layer until the top surface of the ceramic base is exposed.

The arranging of the bonding layer may include arranging a bonding layer made of a material containing at least one of Ag, AgCu and AgCuTi using any one method of plating, paste application, and foil attachment.

After the etching, the upper metal layer may be separated into a plurality of metal patterns.

In the etching, a width of the etched portion of the upper metal layer may be less than a width of the upper pattern groove. A stepped protrusion may be formed on one side surface of each of facing metal patterns.

In addition, respective stages forming a step on the protrusion may have different protrusion lengths.

In addition, each of stages forming a step on the protrusion may have a protrusion length increased as a corresponding stage is closer to the ceramic base.

In addition, any one of stages forming a step on the protrusion may be formed to be concave.

In addition, the ceramic substrate manufacturing method may further include separating the lower metal layer into a plurality of metal patterns.

A ceramic substrate manufacturing method according to another embodiment of the present disclosure may include preparing an upper metal layer and a lower metal layer that are arranged on a top and a bottom of a ceramic base, forming an upper pattern groove having a thickness less than a thickness of the upper metal layer by cutting a partial upper portion of the upper metal layer, forming a photoresist pattern that exposes the upper pattern groove on a top surface of the upper metal layer, and etching a portion of the upper metal layer corresponding to the upper pattern groove by using the photoresist pattern as an etching mask.

In the forming of the upper pattern groove, the upper pattern groove may be formed to have a thickness equal to or greater than 50% and less than or equal to 90% of the thickness of the upper metal layer.

The ceramic substrate manufacturing method may further include, before or after the forming of the upper pattern groove, bonding the upper metal layer to a top of the ceramic base and bonding the lower metal layer to a bottom of the ceramic base.

### Advantageous Effects of Invention

In accordance with the ceramic substrate manufacturing method according to embodiments of the present disclosure, an upper pattern groove is formed by performing a mechanical process in advance so as to form a metal pattern on a metal layer, thus shortening the time required for a chemical etching process of removing the remaining portion corresponding to the upper pattern groove.

Further, in accordance with the ceramic substrate manufacturing method according to embodiments of the present disclosure, the time and cost required to form a metal pattern on an upper metal layer may be reduced, thus not only enabling efficient mass production but also increasing pattern precision and quality.

Furthermore, in accordance with the ceramic substrate manufacturing method according to embodiments of the present disclosure, a stepped protrusion may be formed on one side surface of each of facing metal patterns to reduce thickness in an edge region, thus enhancing resistance to thermal shock under rapid temperature changes, and alleviating thermal stress.

Furthermore, in accordance with the ceramic substrate manufacturing method according to embodiments of the present disclosure, an upper metal layer is formed of any one of Cu, Al, or a Cu alloy and is formed at a thickness of 0.8 mm or more, thus allowing high voltage and high current conduction and obtaining excellent thermal conductivity, with the result that the present disclosure may be applied to a power module for high-output power conversion that requires high reliability.

Furthermore, in accordance with the ceramic substrate manufacturing method according to embodiments of the present disclosure, a lower metal layer is formed of any one of Cu, Al, or a Cu alloy and is formed at a thickness of 0.8 mm or more, thereby satisfying high heat dissipation conditions required by a power module and enhancing reliability by showing strong resistance to thermal shock and thermal fatigue.

### BRIEF DESCRIPTION OF DRAWINGS

FIG. 1 is a perspective view illustrating a ceramic substrate according to an embodiment of the present disclosure.

FIG. 2 is a plan view illustrating a ceramic substrate according to an embodiment of the present disclosure.

FIG. 3 is a sectional view taken along line A-A′ of FIG. 2.

FIG. 4 is a flowchart illustrating a ceramic substrate manufacturing method according to an embodiment of the present disclosure.

FIG. 5 is a view for describing a step of forming an upper pattern groove in the ceramic substrate manufacturing method according to an embodiment of the present disclosure.

FIG. 6 is a view for describing a step of bonding an upper metal layer to the top of a ceramic base and bonding a lower metal layer to the bottom of the ceramic base in the ceramic substrate manufacturing method according to an embodiment of the present disclosure.

FIG. 7 is a view for describing a step of forming a photoresist pattern and a step of etching a portion of an upper metal layer in the ceramic substrate manufacturing method according to an embodiment of the present disclosure.

FIG. 8 is a view for describing a step of etching a portion of a bonding layer until the top surface of a ceramic base is exposed, and a step of removing the photoresist pattern in the ceramic substrate manufacturing method according to an embodiment of the present disclosure.

FIG. 9 is a view for describing a modified example in which the width of an etched portion of the upper metal layer is less than the width of an upper pattern groove in the step of etching the portion of the upper metal layer in FIG. 7.

FIG. 10 is a view illustrating the state in which the exposed portion of the bonding layer and the photoresist pattern in FIG. 9 are removed.

FIG. 11 is a view illustrating a modified example in which any one of stages forming a step in the protrusion of FIG. 10 is formed to be concave.

FIG. 12 is a view illustrating another modified example in which a lower metal layer is separated into a plurality of metal patterns.

FIG. 13 is a flowchart illustrating a ceramic substrate manufacturing method according to another embodiment of the present disclosure.

FIG. 14 is a view for describing a step of forming an upper pattern groove in the ceramic substrate manufacturing method according to the other embodiment of the present disclosure.

### DESCRIPTION OF EMBODIMENTS

Hereinafter, exemplary embodiments of the present disclosure will be described in detail with reference to the attached drawings.

The embodiments are provided to more completely describe the present disclosure to those skilled in the art, the following embodiments may be modified in various different forms, and the scope of the present disclosure is limited to the following embodiments. Rather, the embodiments are provided to make the disclosure more faithful and complete and fully convey the spirit of the present disclosure.

Terms used in the present specification are intended to describe specific embodiments and are not intended to limit the present disclosure. In addition, in the present specification, singular forms may include plural forms unless the context clearly indicates otherwise.

In the description of embodiments, when each layer (film), region, pattern, or structure is described as being formed “on” or “under” a substrate, each layer (film), region, pad, or pattern, the terms “on” and “under” encompass “directly” formed structures or “indirectly” formed structures with the interposition of another layer. In addition, the reference for “on” or “under” with respect to each layer is, in principle, based on the drawings.

Drawings are merely intended to help understanding of the spirit of the present disclosure, and should not be construed as limiting the scope of the present disclosure. Furthermore, the relative thickness, length, or size depicted in the drawings may be exaggerated for the convenience and clarity of description.

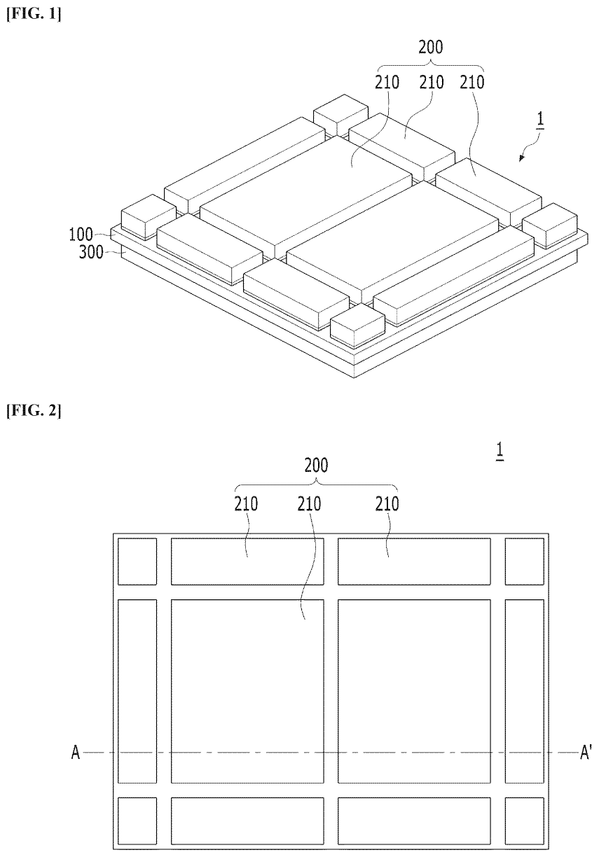

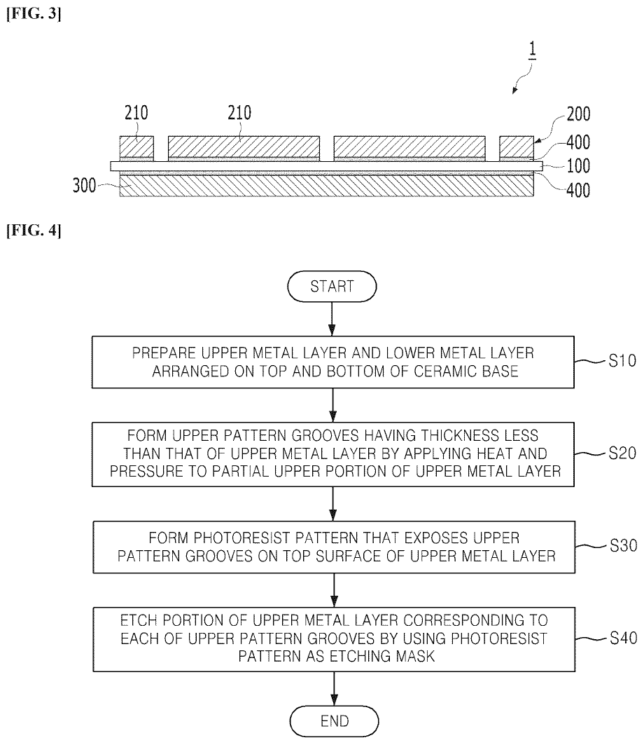

FIG. 1 is a perspective view illustrating a ceramic substrate according to an embodiment of the present disclosure, FIG. 2 is a plan view illustrating a ceramic substrate according to an embodiment of the present disclosure, and FIG. 3 is a sectional view taken along line A-A′ of FIG. 2.

As illustrated in FIGS. 1 to 3, a ceramic substrate 1 according to an embodiment of the present disclosure may include a ceramic base 100, an upper metal layer 200 bonded to the top of the ceramic base 100, and a lower metal layer 300 bonded to the bottom of the ceramic base 100. In the present embodiment, although description is made based on an Active Metal Brazed (AMB) substrate as an example, a Direct Bonding Copper (DBC) substrate may also be applied. Here, the AMB substrate is the most suitable in terms of durability and heat dissipation efficiency.

The ceramic base 100 may be made of an oxide-based or nitride-based ceramic material. For example, the ceramic base 100 may be, but is not limited to, any one of alumina (Al₂O₃), AlN, SiN, Si₃N₄, Zirconia Toughened Alumina (ZTA).

The upper metal layer 200 may be brazed to the top of the ceramic base 100 via a bonding layer 400. The upper metal layer 200 may be made of any one of Cu, Al, or a Cu alloy (CuMo or the like). The upper metal layer 200 may be separated into a plurality of metal patterns 210 so that electrical circuit connection thereof to an electrode of a semiconductor chip (not illustrated) made of Si, LED, VCSEL, SiC, or GaN is enabled. Here, the form of the metal patterns 210 may be designed in various manners depending on the number of semiconductor chips to be mounted or the like.

A process for separating the upper metal layer 200 into the plurality of metal patterns will be described in detail later with reference to FIGS. 4 to 8.

The upper metal layer 200 may be formed to have a thickness of 0.8 mm or more. In the case of a power module where high-power power conversion is performed, the upper metal layer 200 that makes circuit connection to the semiconductor chips needs to have high electric conductivity and to have high thermal conductivity for heat dissipation. Because the ceramic substrate 1 according to the embodiment of the present disclosure is configured such that the upper metal layer 200 is formed of any one of Cu, Al, or a Cu alloy and is formed at a relatively large thickness of 0.8 mm or more, there are advantages in that electrical conductivity and thermal conductivity are excellent, and the ceramic substrate is applicable to a power module for high-power power conversion.

The lower metal layer 300 may be brazed to the bottom of the ceramic base 100 via the bonding layer 400, and may be formed to have a thickness of 0.8 mm or more. The lower metal layer 300 may be made of any one of Cu, Al, or a Cu alloy (CuMo or the like) so as to increase heat dissipation efficiency. The lower metal layer 300 may be formed of a flat plate to increase a bonding area with a heat sink (not illustrated), but is not limited thereto.

The bonding layer 400 may be disposed between the top surface of the ceramic base 100 and the bottom surface of the upper metal layer 200, as well as between the bottom surface of the ceramic base 100 and the top surface of the lower metal layer 300, and may integrally bond the ceramic base 100 to the upper and lower metal layers 200 and 300 at brazing temperature. The brazing temperature may be 450 °C or higher.

The bonding layer 400 may be made of a material containing at least one of Ag, AgCu, and AgCuTi. Because the materials such as Ag, AgCu, and AgCuTi have thermal conductivity of about 350 W/m×K or higher, it may facilitate heat transfer between the ceramic base 100 and the upper and lower metal layers 200 and 300, thus increasing heat dissipation efficiency. Further, the ceramic base 100 and the upper and lower metal layers 200 and 300 may be hermetically bonded to each other through brazing via the bonding layer 400, thus resulting in high bonding strength and excellent high-temperature reliability.

FIG. 4 is a flowchart illustrating a ceramic substrate manufacturing method according to an embodiment of the present disclosure.

As illustrated in FIG. 4, the ceramic substrate manufacturing method according to the embodiment of the present disclosure may include step S10 of preparing an upper metal layer 200 and a lower metal layer 300 that are arranged on the top and bottom of a ceramic base 100, step S20 of forming upper pattern grooves 201 having a thickness less than that of the upper metal layer 200 by applying heat and pressure to a partial upper portion of the upper metal layer 200, step S30 of forming a photoresist pattern 20 that exposes the upper pattern grooves 201 on the top surface of the upper metal layer 200, and step S40 of etching a portion of the upper metal layer 200 corresponding to each of the upper pattern grooves 201 by using the photoresist pattern 20 as an etching mask.

In step S10 of preparing the upper metal layer 200 and the lower metal layer 300, each of the upper metal layer 200 and the lower metal layer 300 is made of any one of Cu, Al, or a Cu alloy and is formed at a relatively large thickness of 0.8 mm or more, thus providing excellent electrical conductivity and thermal conductivity and enabling application to a power module for high-power power conversion.

Referring to FIG. 5, in step S20 of forming the upper pattern grooves 201, the upper pattern grooves 201 having a thickness t2 less than the thickness t1 of the upper metal layer 200 may be formed by applying heat and pressure to the partial upper portion of the upper metal layer 200. Here, the upper metal layer 200 may be seated in a lower press mold 11, and the upper pattern grooves 201 may be formed as pressure is applied by an upper press mold 12. Here, as pressure is applied to the upper metal layer 200 in a high-temperature heated state, the upper pattern grooves 201 having a shape corresponding to processing protrusions 12a of the upper press mold 12 may be formed. Meanwhile, although not illustrated in detail, the upper pattern grooves 201 may also be formed by Numerical Control Turret Press (NCT).

In step S20 of forming the upper pattern grooves 201, the upper pattern grooves 201 may be formed by removing a portion of the upper metal layer 200 within a range of 50% to 90% of the total thickness t1. For example, when the total thickness t1 of the upper metal layer 200 is 10 mm, the upper pattern grooves 201 having a thickness t2 of 7 mm may be formed by removing a partial upper portion of the upper metal layer 200. In addition, when the total thickness t1 of the upper metal layer 200 is 8 mm, the upper pattern grooves 201 having a thickness t2 of 4 mm may be formed by removing a partial upper portion of the upper metal layer 200.

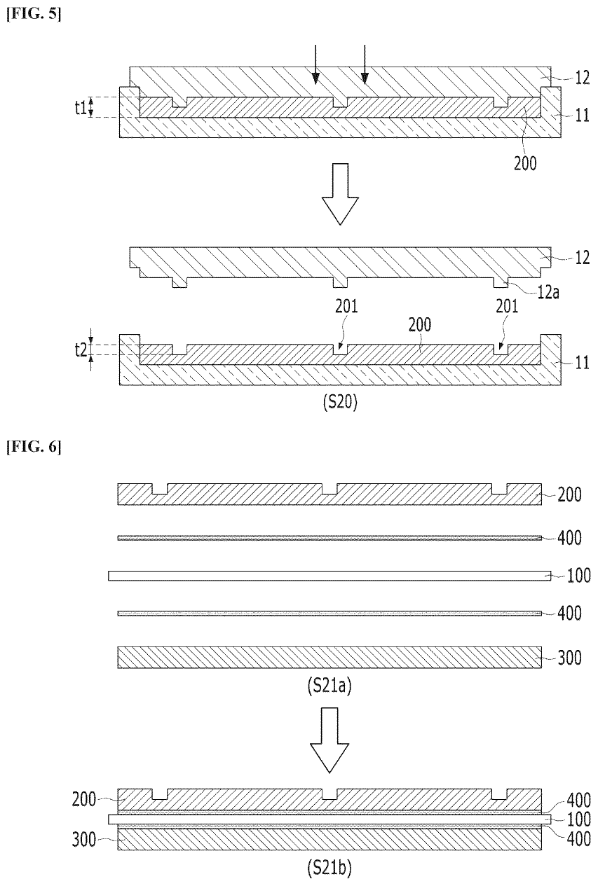

Referring to FIG. 6, after step S20 of forming the upper pattern grooves, the ceramic substrate manufacturing method may further include step S21 of bonding the upper metal layer 200 to the top of the ceramic base 100 and bonding the lower metal layer 300 to the bottom of the ceramic base 100. The bonding step S21 may include step S21a of arranging the bonding layer 400 between the top surface of the ceramic base 100 and the bottom surface of the upper metal layer 200 and between the bottom surface of the ceramic base 100 and the top surface of the lower metal layer 300, and step S21b of bonding the ceramic base 100, the upper metal layer 200, and the lower metal layer 300 by melting the bonding layer 400.

In step S21a of arranging the bonding layer 400, the bonding layer 400 made of a material containing at least one of Ag, AgCu, and AgCuTi may be arranged using a method corresponding to any one of plating, paste application, and foil attachment, and the thickness of the bonding layer 400 may be within a range from about 0.005 mm to 1.0 mm, but the thickness is not limited thereto.

After the step of arranging the bonding layer 400, the step of bonding the ceramic base 100, the upper metal layer 200, and the lower metal layer 300 by melting the bonding layer 400 may be performed. In the bonding step, in the state in which the lower metal layer 300, the ceramic base 100, and the upper metal layer 200 are stacked, the bonding layer 400 interposed between individual layers may be melted at a temperature of 450 °C or higher, desirably within a range of 780 to 900 °C, to achieve brazing, wherein upper weighting or pressurizing may be performed to enhance bonding strength.

Meanwhile, although not illustrated in the drawings, step S21 of bonding the upper metal layer 200 to the top of the ceramic base 100 and bonding the lower metal layer 300 to the bottom of the ceramic base 100 may be performed before step S20 of forming the upper pattern grooves 201. That is, depending on a manufacturing environment, the upper metal layer 200 may be bonded to the ceramic base 100 before the formation of the upper pattern grooves 201, and the upper pattern grooves 201 may be formed in the upper metal layer 200 in the state in which the upper and lower metal layers 200 and 300 are bonded to the ceramic base 100.

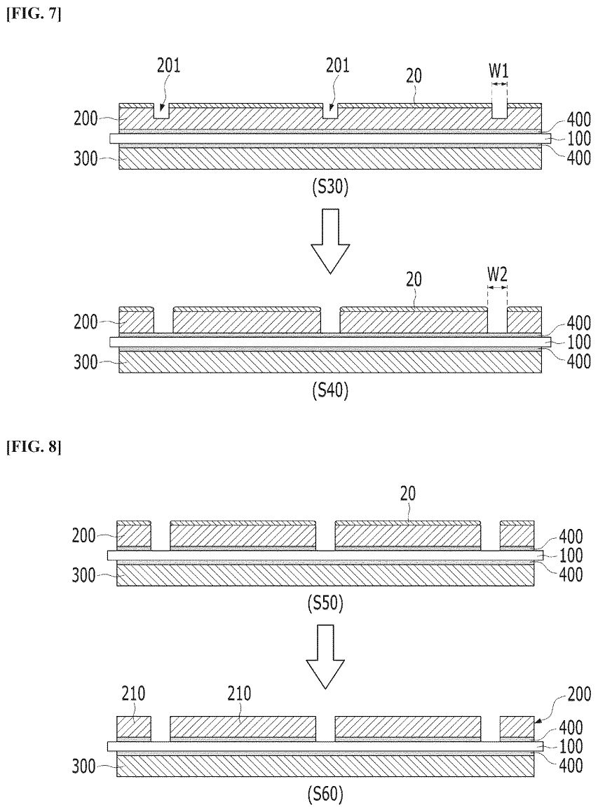

Referring to FIG. 7, in step S30 of forming the photoresist pattern 20 that exposes the upper pattern grooves 201 on the top surface of the upper metal layer 200, the photoresist pattern 20 may be formed by performing a photolithography process on the upper metal layer 200. Although not illustrated in detail, the photolithography process may include forming a photoresist layer, and thereafter forming the photoresist pattern 20 by performing an exposure and development process on the photoresist layer. Here, the photoresist pattern 20 may be formed to expose the upper pattern grooves 201 so as to etch a portion of the upper metal layer 200 corresponding to each of the upper pattern grooves 201.

After step S30 of forming the photoresist pattern 20, step S40 of etching the portion of the upper metal layer 200 corresponding to the upper pattern grooves 201 by using the photoresist pattern 20 as the etching mask may be performed. In step S40 of etching the portion of the upper metal layer 200, the width w2 of the etched portion of the upper metal layer 200 may be greater than the width w1 of the upper pattern grooves 201.

Referring to FIG. 8, the ceramic substrate manufacturing method according to an embodiment of the present disclosure may further include, after step S40 of etching the portion of the upper metal layer 200, step S50 of etching an exposed portion of the bonding layer 400 until the top surface of the ceramic base 100 is exposed. The step S50 of performing etching until the top surface of the ceramic base 100 is exposed may include the step of etching a material formed through a reaction between the ceramic base 100 and the bonding layer 400. For example, when the ceramic base 100 is a nitride-based material such as AlN or Si₃N₄, the ceramic base 100 may react to Ti in the bonding layer 400 to form TiN, and thus the etching step may include the step of etching TiN.

After step S50 of performing etching until the top surface of the ceramic base 100 is exposed, a ceramic substrate 1 in which a plurality of metal patterns are formed may be manufactured by performing step S60 of removing the photoresist pattern 20 through dry etching or wet etching.

In this way, the portion of the upper metal layer 200 and the portion of the bonding layer 400, which correspond to the upper pattern grooves 201, may be etched until the top surface of the ceramic base 100 is exposed, and thus the plurality of separate metal patterns 210 may be formed. Because the plurality of metal patterns are electrically isolated according to the pre-designed circuit pattern, short circuits do not occur when circuit connection to semiconductor chips is made.

When the upper metal layer 200 is formed to be thick to such an extent that the thickness thereof is equal to or greater than 0.8 mm, a problem arises in that forming the electrode pattern using only an etching process not only requires an excessively long etching time but also deteriorates pattern precision. On the other hand, the ceramic substrate manufacturing method according to the present disclosure is advantageous in that the time required for a chemical etching process may be shortened because press processing that is a mechanical processing method is conducted in advance to form the plurality of metal patterns. Press processing may form the upper pattern grooves 201 in a thickness direction by removing a portion of the upper metal layer 200 within a range of 50% to 90% of the total thickness. Therefore, even if the upper metal layer 200 is very thick to such an extent that the thickness thereof is about 10 mm, pre-forming the upper pattern grooves 201 with a thickness of 7 mm may reduce the thickness of the upper metal layer 200 to 3 mm, thus significantly shortening the time required for the etching process. In this way, the ceramic substrate manufacturing method according to the present disclosure has the advantage of not only enabling efficient patterning but also enhancing the precision and quality of the pattern.

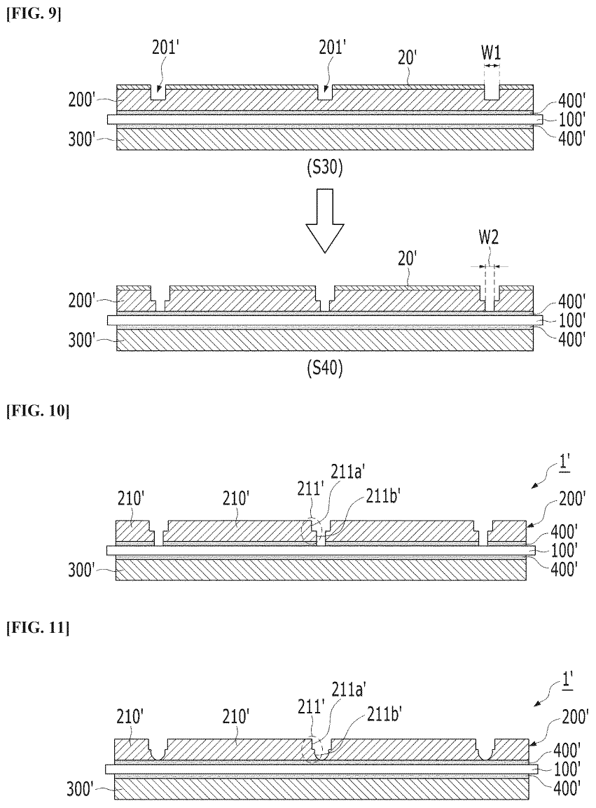

FIG. 9 is a view for describing a modified example in which the width of an etched portion of the upper metal layer is less than the width of the upper pattern groove in the step of etching the portion of the upper metal layer in FIG. 7, and FIG. 10 is a view illustrating the state in which the exposed portion of the bonding layer and the photoresist pattern in FIG. 9 are removed.

Referring to FIG. 9, in step S40 of etching a portion of an upper metal layer 200', the width w2 of the etched portion of the upper metal layer 200′ may be less than the width w1 of each upper pattern groove 201'. When the width w2 of the etched portion of the upper metal layer 200′ is less than the width w1 of the upper pattern groove 201′ in this way, a stepped protrusion 211′ may be formed on one side surface of each of facing metal patterns 210′ in a ceramic substrate 1′, as illustrated in FIG. 10. Here, the stepped shape refers to a shape forming multiple stages. Because an edge region in which stress is concentrated, such as a corner and a boundary, is vulnerable to thermal shock, cracks may occur under rapid temperature changes. On the other hand, when the stepped protrusion 211′ is formed on one side surface of each of the facing metal patterns 210′, the thickness of the edge region may be minimized, and energy in the edge region may be dispersed to alleviate thermal stress.

Respective stages 211a′ and 211b′ forming the step on the protrusion 211′ may be formed to have different protrusion lengths. In detail, the respective stages 211a′ and 211b′ forming the step on the protrusion 211′ may be formed to have protrusion lengths increased as the stages are closer to a ceramic base 100′. That is, the lower stage 211b′ may be formed to protrude beyond the upper stage 211a′. In this way, the protrusion 211′ is advantageous in that the thickness thereof in the edge region decreases, and thus the energy in the edge region is dispersed, with the result that thermal stress may be alleviated and resistance to thermal shock is strong.

FIG. 11 is a view illustrating another modified example in which any one of stages forming a step in the protrusion of FIG. 10 is formed to be concave.

Referring to FIG. 11, any one of stages 211a′ and 211b′ forming a step on the protrusion 211′ may be formed to be concave. For example, the lower stage 211b′ may have a curved slope, and may have a shape concave toward the ceramic base 100′.

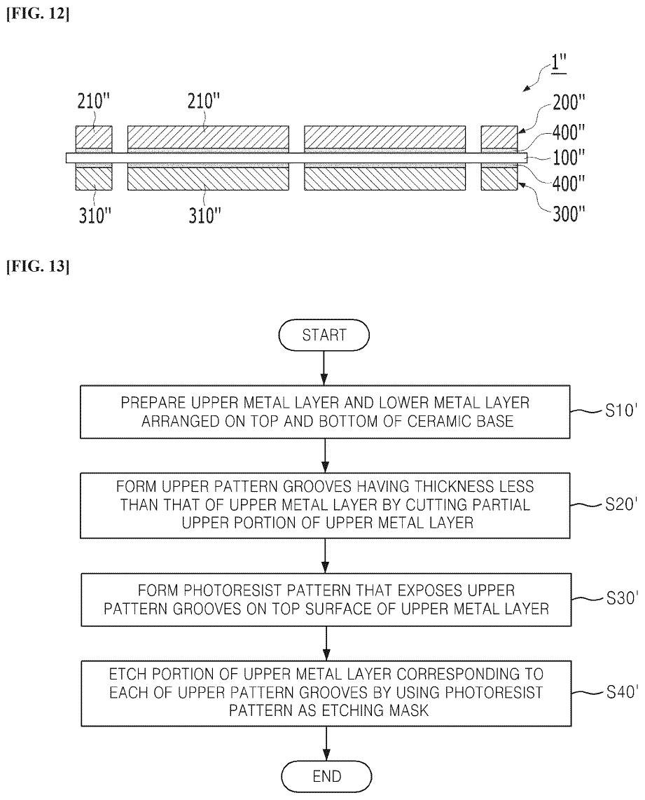

FIG. 12 is a view illustrating a further modified example in which a lower metal layer is separated into a plurality of metal patterns.

Referring to FIG. 12, in a ceramic substrate 1″, a lower metal layer 300″ may be separated into a plurality of metal patterns 310″ and bonded to the bottom surface of a ceramic base 100″. That is, the ceramic substrate manufacturing method according to an embodiment of the present disclosure may further include a step of separating the lower metal layer 300″ into the plurality of metal patterns 310″. Although the lower metal layer 300″ may be formed of a flat plate to increase a bonding area with a heat sink, the lower metal layer 300″ may be formed of a pattern that enables electrical circuit connection with an electrode of a semiconductor chip (not illustrated) made of Si, LED, VCSEL, SiC, or GaN depending on various design forms of a power module. Also, the lower metal layer 300″ may be separated into the plurality of metal patterns 310″ so as to reduce a volume difference with the upper metal layer 200″. That is, when the lower metal layer 300″ is separated into the plurality of metal patterns 310″ to reduce the volume, the volume ratio of the upper metal layer 200″ and the lower metal layer 300″ may be adjusted to fall within a range from 0.9 to 1.1, thus reducing warping in a high-temperature environment. Because, similar to the upper metal layer 200″, the lower metal layer 300″ is a thick Cu layer formed to have a thickness of 0.8 mm or more, a process of separating the lower metal layer into the plurality of metal patterns 310″ may be performed in the same manner as the process of separating the upper metal layer 200″ into the plurality of metal patterns 210″. That is, the step of separating the lower metal layer 300″ into the plurality of metal patterns 310″ may include a step of forming lower pattern grooves having a thickness less than that of the lower metal layer 300″ by applying heat and pressure to the lower metal layer 300″, forming a photoresist pattern that exposes the lower pattern grooves, etching a portion of the lower metal layer 300″ corresponding to each of the lower pattern grooves by using the photoresist pattern as an etching mask, and then etching an exposed portion of the bonding layer until the bottom surface of the ceramic base is exposed. Further, the step of separating the lower metal layer 300″ into the plurality of metal patterns 310″ may be performed before the step of bonding the lower metal layer 300″ to the bottom of the ceramic base 100″.

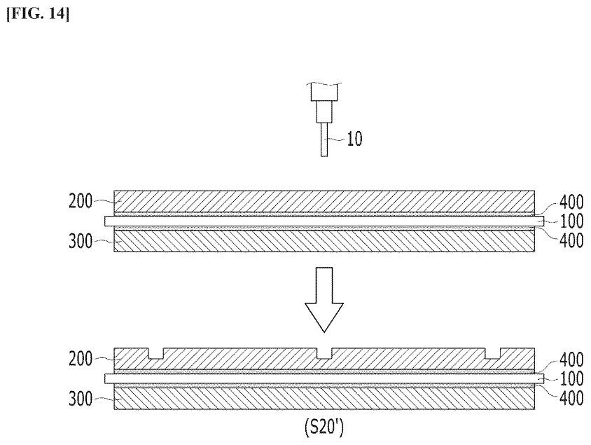

FIG. 13 is a flowchart illustrating a ceramic substrate manufacturing method according to another embodiment of the present disclosure, and FIG. 14 is a view for describing a step of forming upper pattern grooves in the ceramic substrate manufacturing method according to the other embodiment of the present disclosure.

As illustrated in FIG. 13, the ceramic substrate manufacturing method according to the other embodiment of the present disclosure may include step S10′ of preparing an upper metal layer 200 and a lower metal layer 300 that are arranged on the top and bottom of a ceramic base 100, step S20′ of forming upper pattern grooves 201 having a thickness less than that of the upper metal layer 200 by cutting a partial upper portion of the upper metal layer 200, step S30′ of forming a photoresist pattern 20 that exposes the upper pattern grooves 201 on the top surface of the upper metal layer 200, and step S40′ of etching a portion of the upper metal layer 200 corresponding to each of the upper pattern grooves 201 by using the photoresist pattern 20 as an etching mask.

In the ceramic substrate manufacturing method according to the other embodiment of the present disclosure, step S10′ of preparing the upper metal layer 200 and the lower metal layer 300 that are arranged on the top and bottom of the ceramic base 100, step S30′ of forming the photoresist pattern 20 that exposes the upper pattern grooves 201 on the top surface of the upper metal layer 200, and step S40′ of etching the portion of the upper metal layer 200 corresponding to each of the upper pattern grooves 201 by using the photoresist pattern 20 as the etching mask may be performed in the same manner as the one embodiment. In the ceramic substrate manufacturing method according to the other embodiment of the present disclosure, as illustrated in FIG. 14, step S20′ of forming the upper pattern grooves 201 may include forming the upper pattern grooves 201 having a thickness less than that of the upper metal layer 200 by cutting the partial upper portion of the upper metal layer 200. Here, the cutting processing may form the upper pattern grooves 201 in the thickness direction by performing a milling process that is a physical process. Here, the partial upper portion of the upper metal layer 200 may be cut by a milling tip 10, such as an end mill rotating around a rotating shaft, to form the upper pattern grooves 201 in the thickness direction. Although not illustrated in drawings, a milling device (not illustrated) may be provided to freely form the upper pattern grooves 201 with various depths and slopes while moving the milling tip 10 according to a pre-designed pattern. The mechanical processing method using the milling tip 10 has the advantage of enabling the rapid and precise formation of the upper pattern grooves 201 even when the upper metal layer 200 is formed to be thick. That is, since circuit patterns may be freely designed according to semiconductor chips, product specifications, and the like, and micro-patterns may be formed, the design and production of various power modules may be implemented. Further, even if the pattern changes, such a pattern change may be corrected through a computer, thus enabling flexible adaptation to the changed pattern.

The above-described ceramic substrate manufacturing method according to embodiments of the present disclosure is advantageous in that the time required for a chemical etching process may be shortened because press processing or cutting processing that is a mechanical processing method is conducted in advance to form a plurality of electrode patterns. Further, the ceramic substrate manufacturing method according to the present disclosure is advantageous in that it not only enables efficient patterning but also enhances the precision and quality of the pattern.

Furthermore, in the ceramic substrate manufacturing method according to embodiments of the present disclosure, a stepped protrusion may be formed on one side surface of each of facing metal patterns to reduce thickness in an edge region, thus enhancing resistance to thermal shock under rapid temperature changes, and alleviating thermal stress.

The above-described ceramic substrate according to the present disclosure may be applied to various devices that require high power and excellent heat dissipation characteristics in addition to single-sided or double-sided cooling power modules.

The above description is merely the exemplary description of the technical spirit of the present disclosure, and those skilled in the art to which the present disclosure pertains will be able to variously modify and change the present disclosure without departing from the essential characteristics of the present disclosure. Therefore, the embodiments disclosed in the present disclosure are not intended to limit the technical spirit of the present disclosure, but intended to describe the same, and the scope of the technical spirit of the present disclosure is not limited by these embodiments. The scope of the present disclosure should be construed by the appended claims, and all technical spirits within the scope of the claims and equivalents thereof should be construed as being included in the scope of the present disclosure.

1. A ceramic substrate manufacturing method, comprising:
preparing an upper metal layer and a lower metal layer that are arranged on a top and a bottom of a ceramic base;
forming an upper pattern groove having a thickness less than a thickness of the upper metal layer by applying heat and pressure to a partial upper portion of the upper metal layer;
forming a photoresist pattern that exposes the upper pattern groove on a top surface of the upper metal layer; and
etching a portion of the upper metal layer corresponding to the upper pattern groove by using the photoresist pattern as an etching mask.

2. The ceramic substrate manufacturing method of claim 1, wherein:
in the forming of the upper pattern groove,
the upper pattern groove is formed to have a thickness equal to or greater than 50% and less than or equal to 90% of the thickness of the upper metal layer.

3. The ceramic substrate manufacturing method of claim 1, further comprising:
before or after the forming of the upper pattern groove,
bonding the upper metal layer to a top of the ceramic base and bonding the lower metal layer to a bottom of the ceramic base.

4. The ceramic substrate manufacturing method of claim 3, wherein the bonding comprises:
arranging a bonding layer between a top surface of the ceramic base and a bottom surface of the upper metal layer and between a bottom surface of the ceramic base and a top surface of the lower metal layer; and
bonding the ceramic base, the upper metal layer, and the lower metal layer by melting the bonding layer.

5. The ceramic substrate manufacturing method of claim 4, further comprising:
etching an exposed portion of the bonding layer until the top surface of the ceramic base is exposed.

6. The ceramic substrate manufacturing method of claim 4, wherein the arranging of the bonding layer comprises:
arranging a bonding layer made of a material containing at least one of Ag, AgCu and AgCuTi using any one method of plating, paste application, and foil attachment.

7. The ceramic substrate manufacturing method of claim 1, wherein:
after the etching,
the upper metal layer is separated into a plurality of metal patterns.

8. The ceramic substrate manufacturing method of claim 7, wherein:
in the etching,
a width of the etched portion of the upper metal layer is less than a width of the upper pattern groove.

9. The ceramic substrate manufacturing method of claim 8, wherein a stepped protrusion is formed on one side surface of each of facing metal patterns.

10. The ceramic substrate manufacturing method of claim 9, wherein respective stages forming a step on the protrusion have different protrusion lengths.

11. The ceramic substrate manufacturing method of claim 9, wherein each of stages forming a step on the protrusion has a protrusion length increased as a corresponding stage is closer to the ceramic base.

12. The ceramic substrate manufacturing method of claim 9, wherein any one of stages forming a step on the protrusion is formed to be concave.

13. The ceramic substrate manufacturing method of claim 1, further comprising:
separating the lower metal layer into a plurality of metal patterns.

14. A ceramic substrate manufacturing method, comprising:
preparing an upper metal layer and a lower metal layer that are arranged on a top and a bottom of a ceramic base;
forming an upper pattern groove having a thickness less than a thickness of the upper metal layer by cutting a partial upper portion of the upper metal layer;
forming a photoresist pattern that exposes the upper pattern groove on a top surface of the upper metal layer; and
etching a portion of the upper metal layer corresponding to the upper pattern groove by using the photoresist pattern as an etching mask.

15. The ceramic substrate manufacturing method of claim 14, wherein:
in the forming of the upper pattern groove,
the upper pattern groove is formed to have a thickness equal to or greater than 50% and less than or equal to 90% of the thickness of the upper metal layer.

16. The ceramic substrate manufacturing method of claim 14, further comprising:
before or after the forming of the upper pattern groove,
bonding the upper metal layer to a top of the ceramic base and bonding the lower metal layer to a bottom of the ceramic base.
